(19) United States
(12) Patent Application Publication
(10) Pub. No.: US 2018/0119242 A1
(43) Pub. Date: May 3, 2018

(54) METHOD FOR FORMING LINEAR GROOVE ON COLD ROLLED STEEL STRIP AND METHOD FOR MANUFACTURING GRAIN-ORIENTED ELECTRICAL STEEL SHEET

(71) Applicant: JFE STEEL CORPORATION, Chiyoda-ku, Tokyo (JP)

(72) Inventor: Hirokazu KOBAYASHI, Chiyoda-ku, Tokyo (JP)

(73) Assignee: JFE STEEL CORPORATION, Chiyoda-ku, Tokyo (JP)

(21) Appl. No.: 15/529,141

(22) PCT Filed: Dec. 10, 2015
(86) PCT No.: PCT/JP2015/006175

§ 371 Date: May 24, 2017

(30) Foreign Application Priority Data
Dec. 11, 2014 (JP) 2014-251175

(51) Int. Cl. C21D 8/12; C25F 3/06; C25F 3/14; H01F 1/16; G03F 7/40; B23K 26/364

(52) U.S. Cl. CPC C21D 8/1294; C25F 3/06; C25F 3/14; C21D 2201/05; G03F 7/40; B23K 26/364; C21D 8/1255; H01F 1/16

(57) ABSTRACT

A resist coating for etching use which enables high speed and high accuracy patterning is provided by applying, to a cold rolled steel strip, a positive resist ink which solubilizes upon exposure to light; then drying the positive resist ink to form a resist coating; then scanning a laser beam converged in a point shape in the width direction of the cold rolled steel strip to form a photosensitive portion; and then removing the photosensitive portion of the resist film with a developing solution. Subsequently, by dissolving and removing by etching a portion of the steel strip below the removed portion of the resist coating, a fine and uniform linear groove can be formed in a surface of the steel strip.

### TECHNICAL FIELD

This disclosure relates to methods for forming linear grooves on steel strips for grain-oriented electrical steel sheets used for iron cores of electrical equipment such as transformers, and to methods for manufacturing grain-oriented electrical steel sheets by applying the same.

### BACKGROUND

Grain-oriented electrical steel sheets are mainly used as iron core materials of transformers, and are required to have good magnetic properties. In order to reduce energy loss in iron core applications, among magnetic properties, iron loss in particular needs to be reduced.

Conventionally, attempts have been made to reduce iron loss by increasing the electrical resistance of the steel sheet by increasing Si content, making the crystal orientation highly accorded with the (110)[001] orientation, reducing the sheet thickness of the steel sheet, and so on.

However, the use of the above metallurgical methods alone sets limits to iron loss reduction. Therefore, in order to achieve a further reduction in iron loss, other conventional techniques have proposed artificially refining magnetic domains.

One conventional magnetic domain refining method includes irradiating a laser beam onto a surface of a final-annealed steel sheet, as described in PTL 1 (JPS572252B). This method is effective for improving iron loss properties after laser irradiation, yet has a problem of iron loss properties being deteriorated by subsequent stress relief annealing. It is thus not preferable to apply this method to electrical steel sheets for wound cores requiring strain relief annealing.

On the other hand, as a technique capable of suppressing deterioration of iron loss properties even after strain relief annealing, JP2942074B (PTL 2) proposes forming linear grooves by etching after applying a resist ink in a linear pattern.

Further, JP3488333B (PTL 3) describes a method for applying a negative resist for photo etching use to produce a precise linear groove pattern to form linear grooves.

Moreover, JPH569284B (PTL 4) describes a method for forming linear grooves using a linear groove pattern produced by applying a positive resist.

### CITATION LIST

### Patent Literature

PTL 1: JPS572252B

PTL 2: JP2942074B

PTL 3: JP3488333B

PTL 4: JPH569284B

### SUMMARY

### Technical Problem

However, the method of PTL 2 has the problem that when some linear grooves collapse or have discontinuities at the time of applying a resist ink, uniform linear grooves cannot be formed by etching, leading to a variation in magnetic properties.

In addition, such a method for forming a linear pattern by coating described in PTL 2 has the problem of not being able to guarantee sufficient insulation in the vicinity of the boundary between a resist ink-coated portion and a resist ink-uncoated portion where the coating decreases in thickness since the resist ink is caused to flow out under the influence of leveling action.

To address this issue, if severe etching is applied from the beginning in an effort to shorten the etching duration, there arises a problem that causes an increase in the non-uniformity of the groove shape at a portion with a small thickness in the vicinity of the boundary between a resist ink-coated portion and a resist ink-uncoated portion.

Moreover, if a narrower groove pattern is produced to reduce etching load, the resist ink coated in that pattern spreads over the uncoated portion. Hence, the method of PTL 2 has a problem that requires a somewhat wide pattern be formed at an uncoated portion.

In addition, as described in PTL 3, when a negative resist coating material is used, those portions irradiated with light solidify. Thus, in applications for magnetic domain refinement of a grain-oriented electrical steel sheet in which a narrow linear groove pattern is formed, the remaining portion of the resist coating (the solidified portion), becomes the mask portion during etching, constitutes a major part of the resist coating. Therefore, there is a problem that it is necessary to irradiate a large area with light, which is inefficient, and that a large-scale light irradiation device is required.

In this regard, as described in PTL 4, if a positive resist coating material is used, the area to be irradiated with light can be reduced. This technique, however, requires a photomask of a desired pattern, and still has the problem of a difficulty in forming a linear pattern at a fine pitch in the width direction of, especially a continuously-traveling cold rolled steel strip, in a short time and with high accuracy.

It could thus be helpful to provide a method for forming linear grooves on a cold rolled steel strip that can form fine and uniform linear grooves on a continuously-traveling cold rolled steel strip by forming a resist coating for etching use thereon, in a certain pattern without using an exposure photomask at high speed with high accuracy, and etching the steel strip.

It could also be helpful to a method for manufacturing a grain-oriented electrical steel sheet that can form linear grooves on a cold rolled steel strip for a grain-oriented electrical steel sheet by using the above-described linear groove formation method, to thereby produce a grain-oriented electrical steel sheet having excellent magnetic properties.

### Solution to Problem

Specifically, the primary features of the disclosure can be summarized as follows:

1. A method for forming linear grooves on a steel strip, the method comprising: applying, to a continuously-traveling cold rolled steel strip, a positive resist ink which solubilizes upon exposure to light; then drying the positive resist ink to form a resist coating; then scanning a laser beam converged in a point shape in the width direction of the cold rolled steel strip to form a linear photosensitive portion; then removing the photosensitive portion of the resist film with a developing solution; and then performing etching to dissolve and remove a portion of the steel strip below the removed portion of the resist coating, to thereby form a linear groove.

2. The method for forming linear grooves on a cold rolled steel strip according to 1., wherein a thickness of the resist coating is set to 15 μm or less.

3. The method for forming linear grooves on a cold rolled steel strip according to 1., wherein a thickness of the resist coating is set to less than 5 μm.

4. The method for forming linear grooves on a cold rolled steel strip according to any one of 1. to 3., wherein a plurality of the linear grooves are formed at an angle of 30° or less with respect to the width direction of the cold rolled steel strip and at a pitch of 20 mm or less in the longitudinal direction of the cold rolled steel strip.

5. The method for forming linear grooves on a cold rolled steel strip according to any one of 1. to 4., wherein two or more aligners, each being configured to irradiate the cold rolled steel strip with the laser beam, are arranged in the width direction of the steel strip.

6. The method for forming linear grooves on a steel strip according to any one of 1. to 5., wherein the cold rolled strip is irradiated with the laser beam across a width of 1 μm or more and 500 μm or less.

7. The method for forming linear grooves on a cold rolled steel strip according to any one of 1. to 6., wherein a groove depth of each linear groove is set to 5 μm or more.

8. A method for manufacturing a grain-oriented electrical steel sheet, comprising:

heating a silicon steel slab;
then hot rolling the steel slab to obtain a hot-rolled sheet;
optionally subjecting the hot-rolled sheet to hot band annealing;
then subjecting the hot-rolled sheet to cold rolling either once, or twice or more with intermediate annealing performed therebetween, to obtain a cold rolled steel strip;
then subjecting the cold rolled steel strip to decarburization annealing;
then applying an annealing separator to the cold rolled steel strip; and
subsequently subjecting the cold rolled steel strip to final annealing,
wherein a linear groove is formed in a surface of the cold rolled steel strip by applying the method as recited in any one of 1. to 7.

### Advantageous Effect

The present disclosure enables forming fine and uniform linear grooves on a continuously-traveling cold rolled steel strip by forming thereon a resist coating for etching use, in a certain pattern without using an exposure mask at high speed with high accuracy. As a result, a grain-oriented electrical steel sheet having extremely good magnetic properties may be obtained.

### BRIEF DESCRIPTION OF THE DRAWINGS

In the accompanying drawings:

FIG. 1 illustrates an implementation of the present disclosure; and

FIG. 2 illustrates a thick resist coating according to the present disclosure;

### DETAILED DESCRIPTION

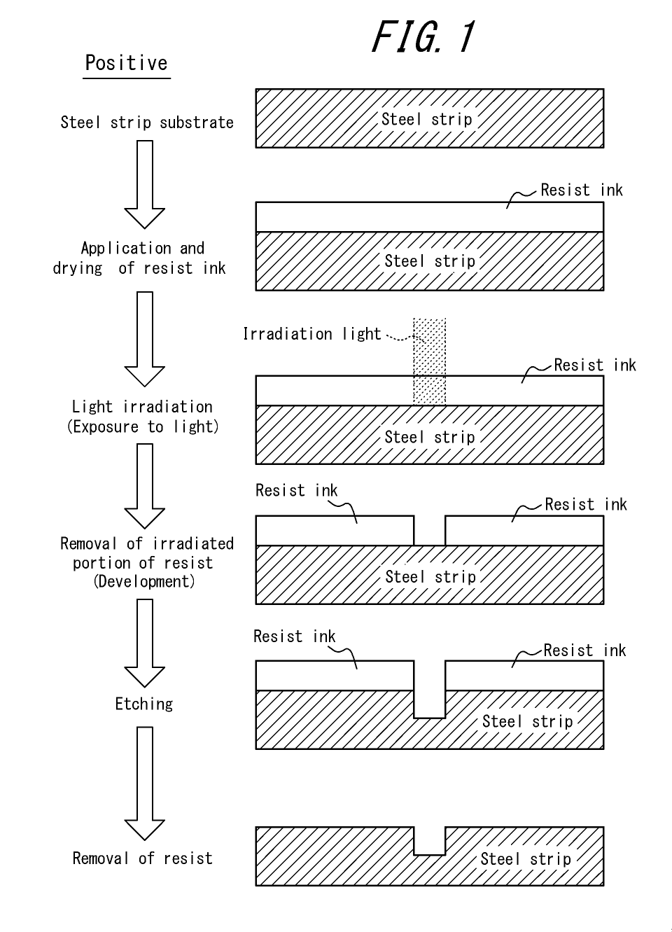

Our methods and products will be described in detail below. The present disclosure relates to a method for forming linear grooves through a process illustrated in FIG. 1 on a cold rolled steel strip (hereinafter, also referred to simply as a steel strip) which is continuously passing by etching (dissolving and removal of a portion of the cold rolled steel strip). First, in the present disclosure, a positive resist ink which solubilizes upon exposure to light is applied to a steel strip using a coater. At this time, the coating method is not particularly limited as long as it is capable of forming a resist coating having a thickness of 15 μm or less in terms of dry coating thickness, and roll coaters and the like that are often used for film coating on steel strips may be used. Besides, a slit die method, a curtain coater method, an ink jet method, a spray method, or the like may be appropriately selected according to the installation space of equipment and the physical properties of the coating material.

In the present disclosure, the resist ink applied is a positive resist ink which is prepared by mixing a photosensitive resin material, which is solubilized by light irradiation, and which allows the portion not irradiated with light to remain as a mask during etching. By using such positive resist ink, there is no need to form a resist ink-coated portion or a resist ink-uncoated portion, and hence grooves will not be interrupted or stuck due to poor coating, allowing for formation of a uniform groove pattern.

The use of such positive resist ink may also prevent the resist ink from spreading to cause collapse of the groove pattern or coating unevenness. In addition, the area to be irradiated with light can be reduced, which enables reducing the load on the irradiation device and shortening the exposure processing time, and as a result forming a groove pattern in a traveling steel strip with high accuracy.

As for drying of the applied resist ink, it suffices as long as the device can guarantee the drying temperature of the coating material, and the device may be selected appropriately from among an induction heating furnace, a hot-air drying furnace, and the like, depending on the factory utility environment and so on.

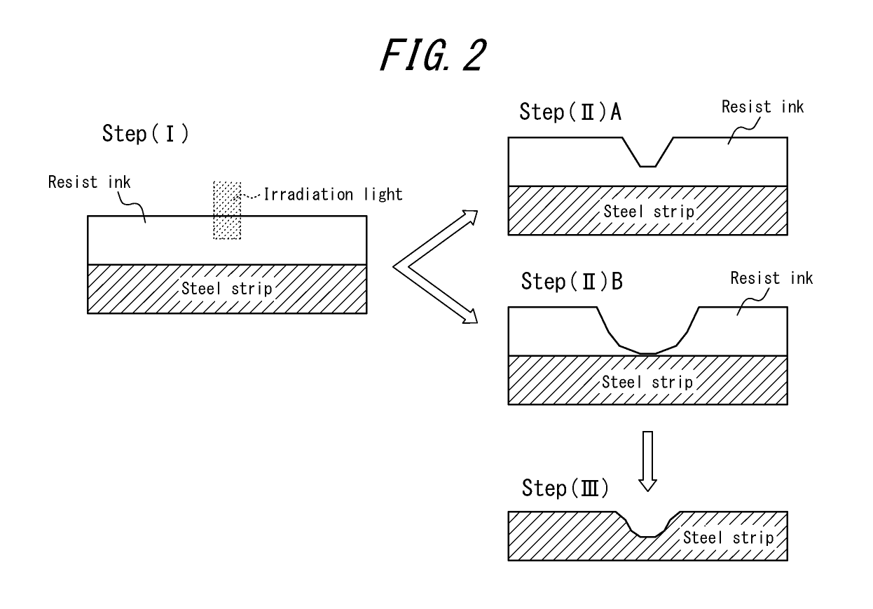

At this time, it is important that the thickness of the resist coating obtained by applying the resist ink and then drying (also called the resist dry coating) is set to 15 μm or less. The reason is that although a reasonable resistance can be secured at the time of etching if the thickness exceeds 15 μm, the coating cannot be exposed sufficiently up to its lower part during light irradiation, making patterning difficult (see step (II)A in FIG. 2).

In addition, when the thickness of the resist coating exceeds 15 μm, severe and long-time exposure is required to sufficiently expose the lower part of the coating, and such exposure also influences the surrounding region (see step (II)B in FIG. 2). Consequently, a rectangular pattern cannot be formed properly, the periphery of the irradiated portion is also solubilized, which leads to a gradient in the coating thickness after removal. If a gradient occurs in the coating thickness, a groove shape defect is caused due to insufficient resistance during etching (see step (III) in FIG. 2), which may cause the magnetic properties to deteriorate.

The resist coating may be thin as long as it can serve as a protective film during the etching of the steel strip. Therefore, the thickness of the resist coating is more preferably less than 5 μm. A resist coating thickness of less than 5 μm reduces deformation of the groove shape. The lower limit for the thickness of the resist coating is not particularly limited, yet in industrial terms it is about 0.5 μm.

In the present disclosure, the thickness of the resist coating is determined by averaging the results from observing the thickness at ten locations randomly selected from a cross section of the coating.

Light irradiation in the present disclosure is carried out using the following light irradiation device. The light irradiation device is configured to irradiate the steel strip with light including a specific wavelength range for solubilizing the resist coating. The light irradiation device comprises features enabling irradiation of the steel strip with a laser beam of light converged in a point shape, and scanning of the steel strip with the laser beam in the width direction of the steel strip to achieve exposure of the steel strip in an intended liner groove pattern. In this case, the scanning angle of the laser beam is set to 50° or less with respect to the normal direction to the surface of the steel strip. If the scanning angle is larger than that, the change in the beam diameter and irradiation intensity of the laser beam converged in a point shape becomes significant, making it difficult to perform exposure with a predetermined accuracy. The scanning angle is preferably 30° or less. This device configuration eliminates the need for an additional device for masking a continuously-traveling steel strip from the light, and enables continuous light irradiation to be performed on a necessary portion at high speed. As used herein, the point shape refers to the shape at the exposure position of a beam of laser light converged to the extent of an exposure width.

As for the light irradiation device, a plurality of the light irradiation devices, preferably two or more light irradiation devices are arranged side by side in the width direction of the steel strip. The reason is that by arranging more than one light irradiation device side by side, it becomes possible to reduce the width to be covered by one unit and to perform the exposure process with high irradiation intensity in a shorter time accordingly, which makes it possible to increase the passing speed of the steel strip.

Linear patterns for exposure (linear grooves) are preferably formed in a pattern in which they are formed at an angle of 30° or less with respect to the width direction of the steel strip. If the angle is larger than that, a sufficient iron loss property improving effect cannot be obtained for the final product. As used herein, the term “linear” is intended to encompass not only straight lines, but also broken lines and continuous lines of points.

In addition, the linear patterns for exposure (linear grooves) are formed in a pattern in which they are formed at a pitch of 20 mm or less in the longitudinal direction of the steel strip. This is because if the pitch is wider than that, a sufficient iron loss property improving effect cannot be obtained. The pitch is preferably 1 mm or more.

Further, it is preferable that the width of exposure (the width of the laser beam) be 1 μm or more and 500 μm or less. The reason is that if the width of exposure is narrower than 1 μm, the width of grooves formed by etching becomes so excessively narrow that it may cause discontinuities in the grooves, and that if the width of exposure is wider than 500 μm a sufficient iron loss property improving effect cannot be obtained.

The way of removing the portion (photosensitive portion) solubilized by the light irradiation of the resist coating is appropriately selected depending on the resist composition, yet an easier way is to immerse in an organic solvent or an alkaline solution. To increase the removal rate of the resist coating, an additional measure may be taken, such as heating the steel strip in advance, increasing the solution temperature, generating a flow in the solution tank, or providing a jet nozzle.

The following describes the process of etching a portion of the steel strip below the removed portion of the resist coating. Etching of the steel strip may be either chemical etching or electrolytic etching, yet electrolytic etching has better controllability since the groove depth can be set by the current passage amount. In the case of electrolytic etching, the electrolysis is preferably performed in an electrolytic bath such as NaCl aqueous solution or KCl aqueous solution, yet there is no particular limitation, and it may be performed in accordance with conventional methods. The groove depth to be etched is preferably 5 μm or more. If the groove depth is shallower than that, a sufficient iron loss property improving effect cannot be obtained. The upper limit for the groove depth to be etched is not particularly limited, yet in industrial terms it is about half the sheet thickness.

The steel strip after subjection to the etching is conveyed to a resist-coating stripping apparatus. Unnecessary portions of the resist coating remaining after the etching, which would adversely affect the downstream processes, are removed by the resist stripping equipment to clean the steel sheet. The stripping process is not particularly specified, yet includes immersing the steel strip in an alkaline solution or an organic solvent such as sodium hydroxide or sodium orthosilicate. Physical stripping means such as brushes and scrapers may be used in combination.

As regards the method for manufacturing a grain-oriented electrical steel sheet, the method comprises: heating a silicon steel slab; then hot rolling the steel slab to obtain a hot-rolled sheet; optionally subjecting the hot-rolled sheet to hot band annealing; then subjecting the hot-rolled sheet to cold rolling either once, or twice or more with intermediate annealing performed therebetween, to obtain a cold rolled steel strip; then subjecting the steel strip to decarburization annealing; then applying an annealing separator to the steel strip; and subsequently subjecting the steel strip to final annealing. In this respect, it is advantageous that the above-described method for forming linear grooves is applied to form a linear groove in a surface of the cold rolled steel strip.

In other words, in manufacturing a grain-oriented electrical steel sheet, magnetic domain refinement may be achieved by forming linear grooves in a surface of the steel strip subjected to the cold rolling by applying the above-described method for forming linear grooves, and the resulting grain-oriented electrical steel sheet may have excellent magnetic properties. After the formation of the linear grooves, the cold rolled steel strip may be subjected to decarburization annealing (primary recrystallization annealing) in accordance with a conventional method and subsequently to final annealing (secondary recrystallization annealing), whereby a grain-oriented electrical steel sheet according to the present disclosure may be obtained.

In the present disclosure, conditions other than those described above, such as the chemical composition of the steel strip, steps for manufacturing the grain-oriented electrical steel sheet, and the like, may be in accordance with conventional methods.

### Examples

Under the respective conditions listed in Table 1, a positive resist ink was applied to each cold rolled steel strip of 0.23 mm in sheet thickness containing 3.3 mass % of Si, which in turn was subjected to drying, light irradiation, removal of a photosensitive portion, and electrolytic etching. Then, after removal of the remaining portion of the resist coating, each steel strip was subjected to decarburization annealing followed by final annealing, and the magnetic properties of each grain-oriented electrical steel sheet thus obtained were evaluated.

In this case, linear grooves were formed at an angle of 10° with respect to the width direction of the corresponding steel strip, at a pitch of 3 mm in the longitudinal direction of the steel strip, with a width of 50 μm, and with a groove depth of 30 μm.

For resist coating formation, a resist ink containing an acrylic group-containing resin, a vinyl ether compound, and the like was used. As a drying furnace, a hot-air drying furnace at a furnace temperature of 250° C. was used for drying. As a laser-type light irradiation device, a UV laser device manufactured by Orbotech was used. As a laser beam, an argon ion laser beam was used. The beam diameter was adjusted to be about 40 μm, and the ultraviolet irradiation dose was set to approximately 50 mW/cm². Removal of the solubilized portions of the resist after exposure was carried out by immersion in an alkaline solution.

As a comparative example, a steel sheet was prepared with a resist ink pattern-printed thereon by offset gravure roll printing following a conventional method, then subjected to etching, and evaluated for magnetic properties.

With regard to the rolls used in the offset gravure roll coater, the gravure roll used was a hard chrome-coated grooved roll and the offset roll was a rubber roll lined with rubber. The gravure roll used had a groove shape such that each uncoated portion was 100 μm in width in the rotation direction and each coated portion was 3 mm in width in the rotation direction. The rubber lining thickness was 20 mm, the rubber was urethane rubber, and the hardness was Hs 80°. The roll diameter was 250 mm for both the gravure roll and the offset roll. The coating liquid used was a resist ink mainly composed of an alkyd-based resin. In use, the resist ink was diluted with ethylene glycol monobutyl ether and adjusted to a viscosity at 20° C. of approximately 1500 mPa·s.

Electrolytic etching was performed for several tens of seconds in an NaCl electrolytic bath at a current density of 30 A/dm² until a groove depth of 30 μm was reached.

In this example, iron loss W_{17/50} was measured at 1.7 T, 50 Hz. As for the appearance, it was determined to be (i) “poor” when discontinuities or deformation was observed in the linear grooves, (ii) “unsatisfactory” or “satisfactory,” which was judged taking into account the results of iron loss evaluation, when a minor variation in groove depth or deformation was observed, or (iii) “excellent” when linear grooves were distinctly formed with a uniform depth.

The iron loss and appearance evaluation results of our examples and the comparative example are listed in Table 1.

[Table 1]

TABLE 1

| | Thicknes of | | | |
|---|---|---|---|---|
| | resist coating | Groove | W_{17/50} | |
| Scheme | [μm] | shape | [W/kg] | Remarks |
| Positive resist | 2 | Excellent | 0.79 | Example |
| Positive resist | 3 | Excellent | 0.78 | Example |
| Positive resist | 4 | Excellent | 0.79 | Example |
| Positive resist | 5 | Good | 0.80 | Example |
| Positive resist | 7 | Good | 0.80 | Example |
| Positive resist | 10 | Good | 0.80 | Example |
| Positive resist | 15 | Good | 0.80 | Example |
| Positive resist | 20 | Fair | 0.81 | Example |
| Gravure offset printing | 3 | Poor | 0.82 | Comparative |
| | | | | Example |

It can be seen from Table 1 that in our examples, the use of a positive resist ink and a laser beam irradiation device enabled, without use of an exposure mask, formation of uniform resist coating patterns and formation of uniform linear grooves by etching. Our examples also gave better results for magnetic properties.

In contrast, the comparative example using conventional offset gravure roll printing gave inferior results for magnetic characteristics after etching, since coating unevenness and spreading of the ink occurred and caused appearance defects and collapse of grooves, preventing stable formation of uniform linear grooves with high accuracy.

Although the above examples have been described in the context of grain-oriented electrical steel sheets being manufactured by using cold rolled steel strips having a thickness of 0.23 mm as substrates, the present disclosure is not so limited. The present disclosure may be equally applied to steel strips of other thicknesses.

1. A method for forming linear grooves on a steel strip, the method comprising: applying, to a continuously-traveling cold rolled steel strip, a positive resist ink which solubilizes upon exposure to light; then drying the positive resist ink to form a resist coating; then scanning a laser beam converged in a point shape in the width direction of the cold rolled steel strip to form a linear photosensitive portion; then removing the photosensitive portion of the resist film with a developing solution; and then performing etching to dissolve and remove a portion of the steel strip below the removed portion of the resist coating, to thereby form a linear groove.

2. The method for forming linear grooves on a cold rolled steel strip according to claim 1, wherein a thickness of the resist coating is set to 15 μm or less.

3. The method for forming linear grooves on a cold rolled steel strip according to claim 1, wherein a thickness of the resist coating is set to less than 5 μm.

4. The method for forming linear grooves on a cold rolled steel strip according to claim 1, wherein a plurality of the linear grooves are formed at an angle of 30° or less with respect to the width direction of the cold rolled steel strip and at a pitch of 20 mm or less in the longitudinal direction of the cold rolled steel strip.

5. The method for forming linear grooves on a cold rolled steel strip according to claim 1, wherein two or more aligners, each being configured to irradiate the cold rolled steel strip with the laser beam, are arranged in the width direction of the steel strip.

6. The method for forming linear grooves on a steel strip according to claim 1, wherein the cold rolled strip is irradiated with the laser beam across a width of 1 μm or more and 500 μm or less.

7. The method for forming linear grooves on a cold rolled steel strip according to claim 1, wherein a groove depth of each linear groove is set to 5 μm or more.

8. A method for manufacturing a grain-oriented electrical steel sheet, comprising:
heating a silicon steel slab;
then hot rolling the steel slab to obtain a hot-rolled sheet;
optionally subjecting the hot-rolled sheet to hot band annealing;
then subjecting the hot-rolled sheet to cold rolling either once, or twice or more with intermediate annealing performed therebetween, to obtain a cold rolled steel strip;
then subjecting the cold rolled steel strip to decarburization annealing;
then applying an annealing separator to the cold rolled steel strip; and
subsequently subjecting the cold rolled steel strip to final annealing,
wherein a linear groove is formed in a surface of the cold rolled steel strip by applying the method as recited in claim 1.

9. A method for manufacturing a grain-oriented electrical steel sheet, comprising:
heating a silicon steel slab;
then hot rolling the steel slab to obtain a hot-rolled sheet;
optionally subjecting the hot-rolled sheet to hot band annealing;
then subjecting the hot-rolled sheet to cold rolling either once, or twice or more with intermediate annealing performed therebetween, to obtain a cold rolled steel strip;
then subjecting the cold rolled steel strip to decarburization annealing;
then applying an annealing separator to the cold rolled steel strip; and
subsequently subjecting the cold rolled steel strip to final annealing,
wherein a linear groove is formed in a surface of the cold rolled steel strip by applying the method as recited in claim 2.

10. A method for manufacturing a grain-oriented electrical steel sheet, comprising:
heating a silicon steel slab;
then hot rolling the steel slab to obtain a hot-rolled sheet;
optionally subjecting the hot-rolled sheet to hot band annealing;
then subjecting the hot-rolled sheet to cold rolling either once, or twice or more with intermediate annealing performed therebetween, to obtain a cold rolled steel strip;
then subjecting the cold rolled steel strip to decarburization annealing;
then applying an annealing separator to the cold rolled steel strip; and
subsequently subjecting the cold rolled steel strip to final annealing,
wherein a linear groove is formed in a surface of the cold rolled steel strip by applying the method as recited in claim 3.

11. A method for manufacturing a grain-oriented electrical steel sheet, comprising:
heating a silicon steel slab;
then hot rolling the steel slab to obtain a hot-rolled sheet;
optionally subjecting the hot-rolled sheet to hot band annealing;
then subjecting the hot-rolled sheet to cold rolling either once, or twice or more with intermediate annealing performed therebetween, to obtain a cold rolled steel strip;
then subjecting the cold rolled steel strip to decarburization annealing;
then applying an annealing separator to the cold rolled steel strip; and
subsequently subjecting the cold rolled steel strip to final annealing,
wherein a linear groove is formed in a surface of the cold rolled steel strip by applying the method as recited in claim 4.

12. A method for manufacturing a grain-oriented electrical steel sheet, comprising:
heating a silicon steel slab;
then hot rolling the steel slab to obtain a hot-rolled sheet;
optionally subjecting the hot-rolled sheet to hot band annealing;
then subjecting the hot-rolled sheet to cold rolling either once, or twice or more with intermediate annealing performed therebetween, to obtain a cold rolled steel strip;
then subjecting the cold rolled steel strip to decarburization annealing;
then applying an annealing separator to the cold rolled steel strip; and
subsequently subjecting the cold rolled steel strip to final annealing,
wherein a linear groove is formed in a surface of the cold rolled steel strip by applying the method as recited in claim 5.

13. A method for manufacturing a grain-oriented electrical steel sheet, comprising:
heating a silicon steel slab;
then hot rolling the steel slab to obtain a hot-rolled sheet;
optionally subjecting the hot-rolled sheet to hot band annealing;
then subjecting the hot-rolled sheet to cold rolling either once, or twice or more with intermediate annealing performed therebetween, to obtain a cold rolled steel strip;
then subjecting the cold rolled steel strip to decarburization annealing;
then applying an annealing separator to the cold rolled steel strip; and
subsequently subjecting the cold rolled steel strip to final annealing,
wherein a linear groove is formed in a surface of the cold rolled steel strip by applying the method as recited in claim 6.

14. A method for manufacturing a grain-oriented electrical steel sheet, comprising:
heating a silicon steel slab;
then hot rolling the steel slab to obtain a hot-rolled sheet;
optionally subjecting the hot-rolled sheet to hot band annealing;
then subjecting the hot-rolled sheet to cold rolling either once, or twice or more with intermediate annealing performed therebetween, to obtain a cold rolled steel strip;
then subjecting the cold rolled steel strip to decarburization annealing;
then applying an annealing separator to the cold rolled steel strip; and
subsequently subjecting the cold rolled steel strip to final annealing,
wherein a linear groove is formed in a surface of the cold rolled steel strip by applying the method as recited in claim 7.

15. The method for forming linear grooves on a cold rolled steel strip according to claim 2, wherein a plurality of the linear grooves are formed at an angle of 30° or less with respect to the width direction of the cold rolled steel strip and at a pitch of 20 mm or less in the longitudinal direction of the cold rolled steel strip.

16. The method for forming linear grooves on a cold rolled steel strip according to claim 2, wherein two or more aligners, each being configured to irradiate the cold rolled steel strip with the laser beam, are arranged in the width direction of the steel strip.

17. The method for forming linear grooves on a steel strip according to claim 2, wherein the cold rolled strip is irradiated with the laser beam across a width of 1 μm or more and 500 μm or less.

18. The method for forming linear grooves on a cold rolled steel strip according to claim 2, wherein a groove depth of each linear groove is set to 5 μm or more.
